(19) United States
(12) Patent Application Publication
(10) Pub. No.: US 2017/0117303 A1
(43) Pub. Date: Apr. 27, 2017

(54) DISPLAY DEVICE

(71) Applicant: InnoLux Corporation, Miao-Li County (TW)

(72) Inventors: Kuan-Feng LEE, Miao-Li County (TW); Yuan-Lin WU, Miao-Li County (TW); Shou-Pu YEH, Miao-Li County (TW)

(21) Appl. No.: 15/333,232

(22) Filed: Oct. 25, 2016

(30) Foreign Application Priority Data
Oct. 27, 2015 (TW) 104135223

(51) Int. Cl. H01L 27/12; H01L 21/66; H01L 29/786

(52) U.S. Cl. CPC H01L 27/1233; H01L 27/1225; H01L 29/78696; H01L 29/7869; H01L 29/78678; H01L 27/127; H01L 22/14

(57) ABSTRACT

A display device is disclosed, which includes: a substrate having a display region; and a first thin film transistor (TFT) unit disposed on the display region and comprising: a first gate electrode disposed on the substrate; a first insulating layer disposed on the first gate electrode; a first semiconductor layer disposed on the first insulating layer, wherein the first semiconductor layer has a top surface which comprises a concave region and a non-concave region; and a first source electrode and a first drain electrode disposed on the top surface of the first semiconductor layer, wherein the first semiconductor layer has a first thickness corresponding to the concave region, and the first semiconductor layer has a second thickness corresponding to the non-concave region, wherein the second thickness is greater than the first thickness.

### CROSS REFERENCE TO RELATED APPLICATION

This application claims the benefits of the Taiwan Patent Application Serial Number 104135223, filed on Oct. 27, 2015, the subject matter of which is incorporated herein by reference.

### BACKGROUND

1. Field of the Invention

The present disclosure relates to a display device, and more particularly, to a display device having thin film transistor (TFT) units disposed on the display region.

2. Description of Related Art

As display technology advances, all display devices are now being developed toward having smaller volume, thinner thickness, and lighter weight. Hence, conventional cathode ray tube (CRT) display has been replaced gradually by thin displays, such as liquid crystal display (LCD) devices, organic light emitting diode (OLED) display devices, or light emitting diode display devices. Thin displays are applied in various fields. For example, display devices used in daily life, such as mobile phones, laptop computers, video cameras, cameras, music players, mobile navigation devices, and televisions, are equipped with thin displays.

### SUMMARY

The display device of the present disclosure comprises: a substrate having a display region; and a first thin film transistor (TFT) unit disposed on the display region and comprising: a first gate electrode disposed on the substrate; a first insulating layer disposed on the first gate electrode; a first semiconductor layer disposed on the first insulating layer, wherein the first semiconductor layer has a top surface which comprises a concave region and a non-concave region; and a first source electrode and a first drain electrode disposed on the top surface of the first semiconductor layer, wherein the first semiconductor layer has a first thickness corresponding to the concave region, and the first semiconductor layer has a second thickness corresponding to the non-concave region, wherein the second thickness is greater than the first thickness.

In the display device of the present disclosure, the substrate may have a non-display region located beside the display region, and the display device further comprising a second thin film transistor unit disposed on the non-display region, and the second thin film transistor unit comprises a polycrystalline-silicon semiconductor. In one example, the second thin film transistor unit comprises: a second gate electrode disposed on the substrate; a second insulating layer disposed on the second gate electrode; a second semiconductor layer disposed on the second insulating layer; and a second source electrode and a second drain electrode disposed on the second semiconductor layer, wherein the second semiconductor layer has a third thickness, and the third thickness is greater than the first thickness.

In the display device of the present disclosure, a difference between the first thickness and the second thickness may be ranged from 50 Å to 500 Å, or may be ranged from 60 Å to 200 Å. The difference between the first thickness and the second thickness may also be ranged from 10% of the second thickness to 100% of the second thickness.

In the display device of the present disclosure, the material of the first semiconductor layer or the material of the second semiconductor layer can comprise, for example, metal oxide, such as IGZO, AIZO, HIZO, ITZO, IGZTO, or IGTO.

In the display device of the present disclosure, the first semiconductor layer may comprise a first part and a second part which respectively corresponding to the first source electrode and the first drain electrode. According to an embodiment of the display device of the present disclosure, the concave region comprises two separated regions each disposed respectively at the first part and at the second part. In another embodiment of the display device of the present disclosure, the concave region is disposed at the first part, the second part, and a third part between the first part and the second part. In another embodiment of the display device of the present disclosure, the concave region is disposed partially at a third part between the first part and the second part. In another embodiment of the display device of the present disclosure, the concave region is disposed entirely at a third part between the first part and the second part.

In the display device of the present disclosure, the first thickness of the first semiconductor layer of the first thin film transistor unit disposed on the display region is less than the third thickness of the second semiconductor layer of the second thin film transistor unit disposed on the non-display region. In particular, in the display device of the present disclosure, a top surface of the first semiconductor layer comprises a concave region and a non-concave region. The defect of the film caused by the concave region can decrease the effect of negative gate stress on the performance of the first thin film transistor unit and further enhance the property of the first thin film transistor unit. In addition, since the second thin film transistor unit disposed on the non-display region is used as a gate drive circuit; thus, the second semiconductor layer of the second thin film transistor unit at this region does not comprise any concave region. Thereby, the negative effect of current stress on the performance of the second thin film transistor unit can be reduced.

Other objects, advantages, and novel features of the present disclosure will become more apparent from the following detailed description when taken in conjunction with the accompanying drawings.

### BRIEF DESCRIPTION OF THE DRAWINGS

FIG. 1A is a top view of a display device according to Example 1 of the present disclosure.

FIG. 1B is a cross-sectional view of a display device according to Example 1 of the present disclosure.

FIG. 2 is a top view of a first thin film transistor unit disposed on the display region of a display device according to Example 1 of the present disclosure.

FIG. 3 is a cross-sectional view of a first thin film transistor unit disposed on the display region of a display device according to Example 1 of the present disclosure.

FIG. 4 is a top view of a second thin film transistor unit disposed on the non-display region of a display device according to Example 1 of the present disclosure.

FIG. 5 is a cross-sectional view of a second thin film transistor unit disposed on the non-display region of a display device according to Example 1 of the present disclosure.

FIG. 6 is a cross-sectional view of a first thin film transistor unit disposed on the display region and a second thin film transistor unit disposed on the non-display region of a display device according to Example 1 of the present disclosure.

FIG. 7A is an Id-Vg curve of a first thin film transistor unit tested under current stress according to Example 1 of the present disclosure.

FIG. 7B is an Id-Vg curve of a first thin film transistor unit tested under negative gate stress according to Example 1 of the present disclosure.

FIG. 7C is an Id-Vg curve of a first thin film transistor unit tested under negative gate stress and back light stress according to Example 1 of the present disclosure.

FIG. 8A is an Id-Vg curve of a second thin film transistor unit tested under current stress according to Example 1 of the present disclosure.

FIG. 8B is an Id-Vg curve of a second thin film transistor unit tested under negative gate stress according to Example 1 of the present disclosure.

FIG. 8C is an Id-Vg curve of a second thin film transistor unit tested under negative gate stress and back light stress according to Example 1 of the present disclosure.

FIG. 9 is a top view of a first thin film transistor unit disposed on the display region of a display device according to Example 2 of the present disclosure.

FIG. 10 is a top view of a first thin film transistor unit disposed on the display region of a display device according to Example 3 of the present disclosure.

FIG. 11 is a top view of a first thin film transistor unit disposed on the display region of a display device according to Example 4 of the present disclosure.

FIG. 12A is a top view of a first thin film transistor unit disposed on the display region of a display device according to Example 5 of the present disclosure.

FIG. 12B is a cross-sectional view of a first thin film transistor unit disposed on the display region of a display device according to Example 5 of the present disclosure.

FIG. 13 is a cross-sectional view of a first thin film transistor unit disposed on the display region of a display device according to Example 6 of the present disclosure.

### DETAILED DESCRIPTION OF EMBODIMENTS

The present disclosure has been described in an illustrative manner. It is to be understood that the terminologies used are intended to be in the nature of description rather than of limitation. Many modifications and variations of the present disclosure are possible in light of the above teachings. Therefore, it is to be understood that within the scope of the appended claims, the disclosure may be practiced otherwise than as specifically described.

In addition, terms, such as first and second, do not have any specific meanings. These terms are only used to distinguish items having the same name.

### Example 1

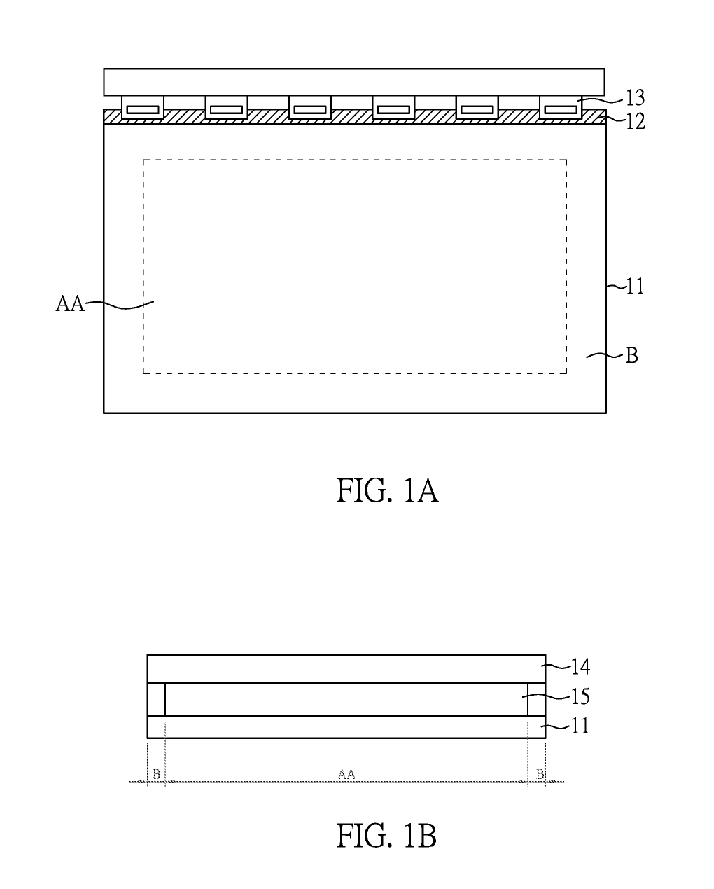

FIG. 1A is a top view of a display device of the present example. The display device of the present example comprises a substrate 11 with a display region AA and a non-display region B. The non-display region B is located beside the display region AA. In the present example, the non-display region B surrounds the display region AA. In other examples, multiple non-display regions B and multiple display regions AA of the substrate 11 are arranged alternatively. The display device of the present example further comprises source drive ICs 13, which are electrically connected with circuit lines 12 on the non-display region B of the substrate 11. Furthermore, in the display device of the present example, gate drive ICs (not shown in the figure) are constructed in the thin film transistor array (not shown in the figure). Therefore, it is a GOP circuit and the gate drive ICs are on the non-display region B. However, in other examples, the source drive ICs 13 are constructed in the thin film transistor array. Or, in other examples, the gate driver ICs are chips bonded on a flexible printed circuit or on the non-display region B.

FIG. 1B is a cross-sectional view of a display device of the present example. The display device of the present example comprises: a counter substrate 14 disposed correspondingly to the substrate 11; and a display layer 15 disposed between the counter substrate 14 and the substrate 11. In the present example, the substrate 11 can be a substrate with thin film transistor units disposed thereon (not shown in the figure), which is a thin film transistor substrate. The counter substrate 14 can be a substrate with a color filter layer disposed thereon (not shown in the figure), which is a color filter substrate. However, in other examples of the present disclosure, the color filter layer (not shown in the figure) can also be disposed on the substrate 11. In this case, the substrate 11 is a thin film transistor substrate integrated with a color filter array (color filter on array, COA). Or, the substrate 11 is a thin film transistor substrate integrated with a black matrix (black matrix on array, BOA). Further, the substrate 11 and the counter substrate 14 can be a rigid substrate or a flexible substrate. In addition, the display layer 15 of the display device of the present example can be a layer of liquid crystals, a layer of organic light emitting diodes, or a layer of light emitting diodes. When the display layer 15 is a layer of liquid crystals, the display device of the present example further comprises a back light module disposed under the substrate 11.

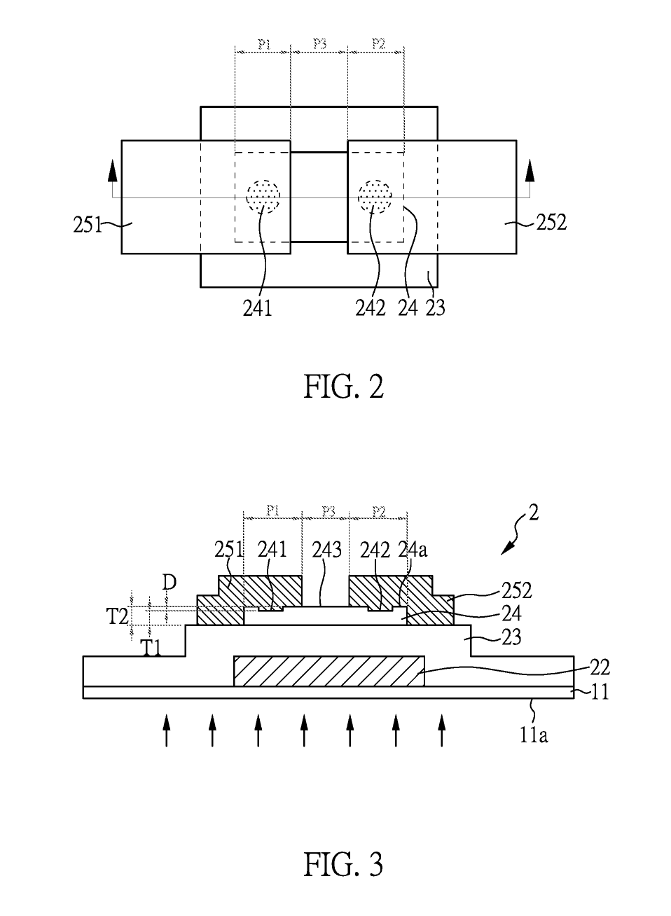

FIG. 2 and FIG. 3 are respectively a top view and a cross-sectional view of a first thin film transistor unit disposed on the display region AA of a display device of the present example. First, a first gate electrode 22 was formed on the substrate 11. A first insulating layer 23 serving as a gate insulating layer was then formed on the first gate electrode 22 and the substrate 11. A first semiconductor layer 24 was then formed on the first insulating layer 23. After the first semiconductor layer 24 was deposited, an etch process was performed to form at least one concave region 241, 242 on a top surface of the first semiconductor layer 24. The etch process is for example but not limit to a wet etch process. The etch solution used by the wet etch process can be changed according to the materials of the first semiconductor layer 24. For example, the etch solution can be a fluoride ion containing-etch solution. After the wet etch process, the ions in the wet etch solution were partially doped in the first semiconductor layer 24 due to the interactions between the ions of the wet etch solution and the first semiconductor layer 24, creating defects in the first semiconductor layer 24 at the concave regions 241, 242. Then, a first source electrode 251 and a first drain electrode 252 were formed on the first semiconductor layer 24. Note that the manufacturing process of the first thin film transistor is not limited to the above sequence.

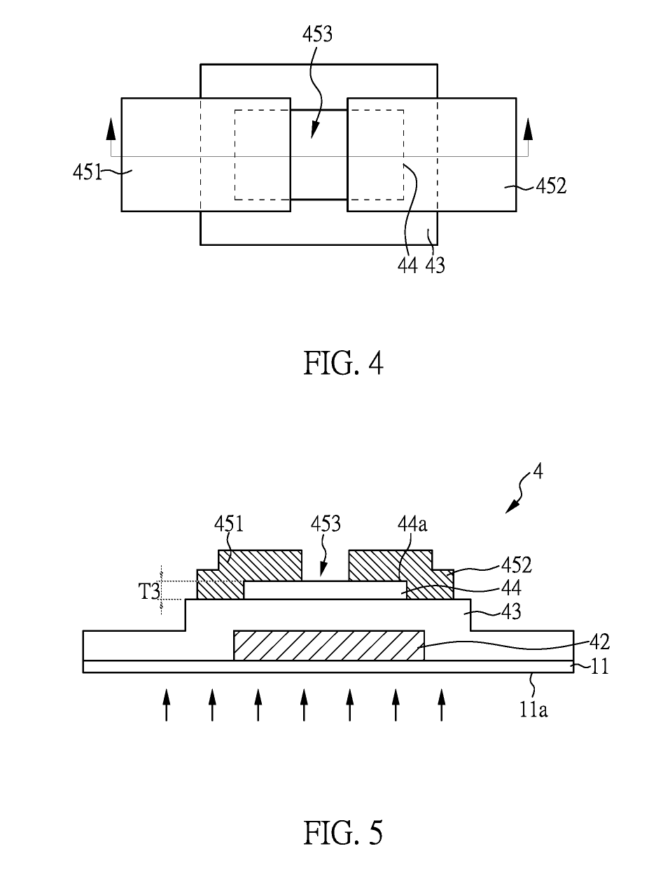

FIG. 4 and FIG. 5 are respectively a top view and a cross-sectional view of a second thin film transistor unit disposed on the non-display region B of a display device of the present example. In the present example, the manufacturing process of the thin film transistor unit disposed on the display region AA and the manufacturing process of the thin film transistor unit disposed on the non-display region B are similar. However, the second semiconductor layer 44 of the second thin film transistor (TFT) unit 4 disposed on the non-display region B does not have concave regions. A second gate electrode 42 was formed on the substrate 11. Second, a second insulating layer 43 serving as a gate insulating layer was formed on the second gate electrode 42 and the substrate 11. A second semiconductor layer 44 was then formed on the second insulating layer 43. Then, a second source electrode 451 and a second drain electrode 452 were formed on the second semiconductor layer 44. It should be noted that, in the present example, the second thin film transistor (TFT) unit 4 disposed on the non-display region B is a bottom gate type transistor with an oxide or amorphous semiconductor. But the disclosure is not limited thereto. The second thin film transistor (TFT) unit 4 can be a top gate type transistor with a polycrystalline-silicon semiconductor. Note that the manufacturing process of the first thin film transistor is not limited to the above sequence. For example, the step of forming the semiconductor layer is before the step of forming the gate electrode when manufacturing a top gate type transistor.

In the present example, the substrate 11 can comprise substrate materials, such as glass, plastic, or flexible materials. The first insulating layer 23 and the second insulating layer 43 can be formed at the same time or at different times. Both of these layers can comprise insulating materials, such as silicon oxide, silicon nitride, silicon oxynitride, or a combination thereof. However, the insulating material is not limited to the above example. The first gate electrode 22 and the second gate electrode 42 can be formed at the same time or at different times. The first source electrode 251, the first drain electrode 252, the second source electrode 451, and the second drain electrode 452 can be formed at the same time or at different times. These electrode units can comprise conducting materials, such as metal, alloy, metal oxide, metal nitrogen oxide, or other electrode materials. The first semiconductor layer 24 and the second semiconductor layer 44 can be formed at the same time or at different times and they can comprise amorphous silicon, polycrystalline-silicon, or metal oxide such as IGZO (indium galium zinc oxide), AIZO (alumimun indium zinc oxide), HIZO (hafnium indium gallium zinc oxide), ITZO (indium tin zinc oxide), IGZTO (indium gallium zinc tin oxide), or metal oxide of IGTO (indium gallium tin oxide). However, in other examples of the present disclosure, the materials of the aforesaid units are not limited thereto.

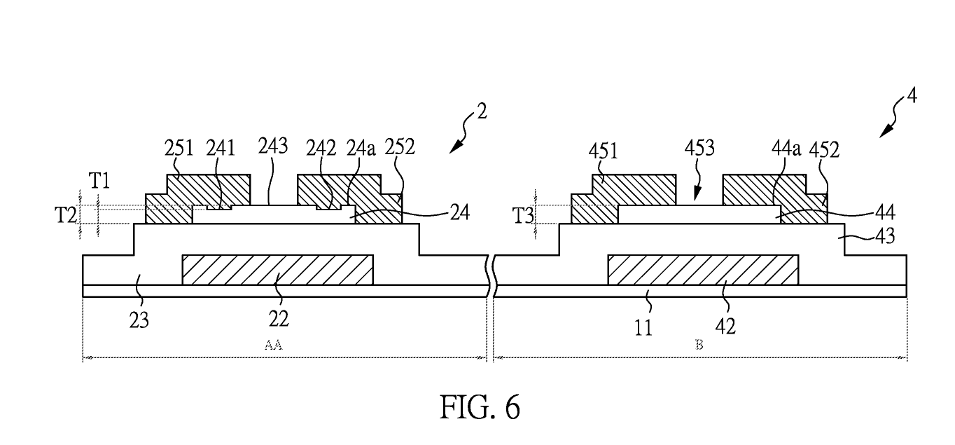

After the aforementioned manufacturing process, the display device of the present example is as shown in FIG. 1A and FIG. 6. The display device of the present example comprises: a substrate 11 with a display region AA and a non-display region B surrounding the display region AA; a first thin film transistor (TFT) unit 2 disposed on the display region AA; and a second thin film transistor (TFT) unit 4 disposed on the non-display region B. As shown in FIG. 2, FIG. 3, and FIG. 6, the first thin film transistor (TFT) unit 2 comprises: a first gate electrode 22 disposed on the substrate 11; a first insulating layer 23 disposed on the first gate electrode 22; a first semiconductor layer 24 disposed on the first insulating layer 23 and disposed correspondingly to the first gate electrode 22, wherein the first semiconductor layer 24 comprises a first part P1 and a second part P2, and a third part P3 between the first part P1 and the second part P2; and a first source electrode 251 and a first drain electrode 252 disposed respectively on the first part P1 and the second part P2 of the first semiconductor layer 24 and connected to the first semiconductor layer 24; wherein there are concave regions 241, 242 on a top surface 24a of the first semiconductor layer 24 respectively facing the first source electrode 251 and the first drain electrode 252, and the concave regions 241, 242 are two separated regions disposed respectively at the first part P1 and the second part P2. In addition, as shown in FIG. 4 to FIG. 6, the second thin film transistor (TFT) unit 4 comprises: a second gate electrode 42 disposed on the substrate 11; a second insulating layer 43 disposed on the second gate electrode 42; a second semiconductor layer 44 disposed on the second insulating layer 43 and disposed correspondingly to the second gate electrode 42, the second semiconductor layer 44 further comprises a channel portion 453 between the second source electrode 451 and the second drain electrode 452; and a second source electrode 451 and a second drain electrode 452 disposed on the second semiconductor layer 44 and connected to the second semiconductor layer 44; wherein, there is a planar region on a top surface 44a of the second semiconductor layer 44 facing the second source electrode 451 and the second drain electrode 452. Note that the top surface 44a of the second semiconductor layer 44 is so called a planar region compared to the top surface 24a of the first semiconductor layer 24 with the concave regions 241, 242. In other words, the planar region is a comparatively descriptive term rather than an exactly descriptive term.

As shown in FIG. 2, the top surface 24a of the first semiconductor layer 24 comprises concave regions 241, 242 and a non-concave region 243. The non-concave region 243 can be regarded as any region of the top surface of the first semiconductor layer 24 except for the concave region 241, 242. The first semiconductor layer 24 corresponding to the concave regions 241, 242 have substantially the same first thickness T1 respectively, and the first semiconductor layer 24 corresponding to the non-concave region 243 has a second thickness T2, wherein the first thickness T1 is smaller than the second thickness T2. In other examples, the semiconductor layer 24 corresponding to the concave regions 241, 242 have different thickness respectively, but each of their thickness is smaller than the second thickness T2. A difference between the first thickness T1 and the second thickness T2 (the depth D of the concave regions 241, 242 of the first semiconductor layer 24) for example can be 50 Å and 500 Å, or can be between 60 Å and 200 Å. But the difference is not limited to the above range. Alternatively, in other examples of the present disclosure, the difference between the first thickness T1 and the second thickness T2 (the depth D of the concave regions 241, 242 of the first semiconductor layer 24) can be 10-100% of the second thickness T2 of the first semiconductor layer 24. In other words, the first thickness T1 and the second thickness T2 may satisfy the following equation 1:

10%×T2≦T2−T1≦100%×T2

In addition, as shown in FIG. 3, the shape of the concave regions 241, 242 of the first semiconductor layer 24 is not particularly limited. The shape can be circle as shown in the present example, polygonal, or irregular. Furthermore, in the display device of the present example as shown in FIG. 2, at a cross-sectional line, the side-walls of the semiconductor layer 24 around the concave regions 241, 242 are perpendicular to the top surface 24a. However, in other examples of the present disclosure, at a cross-sectional line, the side-walls of the concave regions 241, 242 can be inclined sides or curved sides. In these cases, the depth D of the concave regions 241, 242 refers to the largest depth.

In the present example, as shown in FIG. 6, the first semiconductor layer 24 has a first thickness T1 and the second semiconductor layer 44 has a third thickness T3, wherein the first thickness T1 is less than the third thickness T3. The difference between the first thickness T1 and the third thickness T3 is not particularly limited. However, a difference between the first thickness T1 and the third thickness T3 can be between 50 Å and 500 Å, or can be between 60 Å and 200 Å. Alternatively, in other examples of the present disclosure, the difference between the first thickness T1 and the third thickness T3 can be 10-100% of a thickness of the first semiconductor layer 24 (which is a second thickness T2). In other words, the first thickness T1, the second thickness T2 and the third thickness T3 may satisfy the following equation 2:

10%×T2≦T3−T1≦100%×T2

The characteristics of the first thin film transistor 2 (as shown in FIG. 2 and FIG. 3) and the second thin film transistor 4 (as shown in FIG. 4 and FIG. 5) manufactured in Example 1 as switches were tested. The material of the first semiconductor layer 24 of the first thin film transistor 2 and the material of the second semiconductor layer 44 of the second thin film transistor 4 are both IGZO. The first insulating layer 23 and the second insulating layer 43 both comprise a multilayer structure which comprises a stack of silicon oxide and silicon nitride. However, the present disclosure is not limited thereto. The first gate electrode 22 and the second gate electrode 42 are both metal electrodes comprising aluminum as the bottom layer and molybdenum as the top layer. However, the present disclosure is not limited thereto. The materials of the first gate electrode 22 and the second gate electrode 42 can be copper based or silver based materials. The first source electrode 251, the first drain electrode 252, the second source electrode 451 and the second drain electrode 452 are all metal electrodes each comprising a multilayer structure, such as one layer of aluminum between two layers of molybdenum (Mo/Al/Mo). However, the present disclosure is not limited thereto. The materials of these source and drain electrodes can be copper based or silver based materials. The thickness T of the first semiconductor layer 24 and the thickness T of the second thin film transistor unit 4 are both about 625 Å. The depth D of the concave regions 241, 242 of the first semiconductor layer 24 is about 200 Å.

The test conditions under current stress are as follows: Vg=35 V, Vd=20 V, Vs=0 V, test temperature is 70° C. The test times are 0, 15, 30, 45, 60 minutes respectively. The stability of thin film transistor units was tested as large current flowed through it.

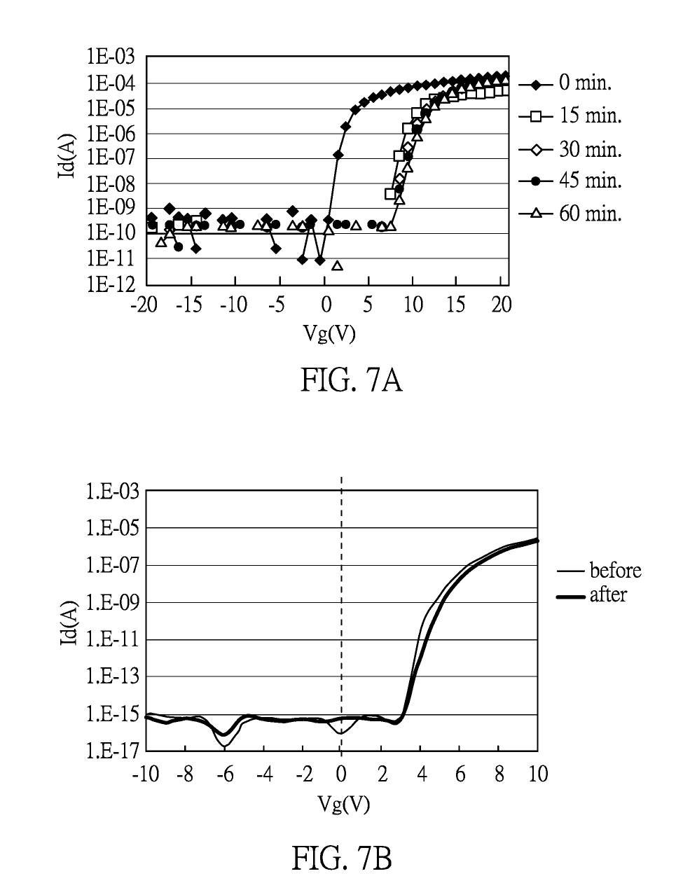

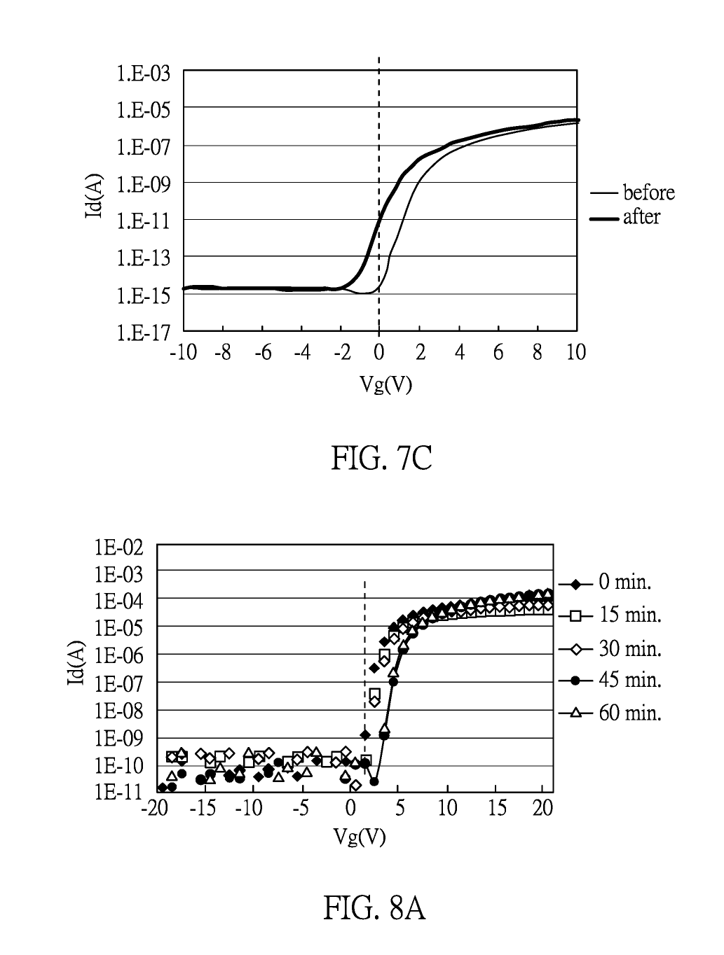

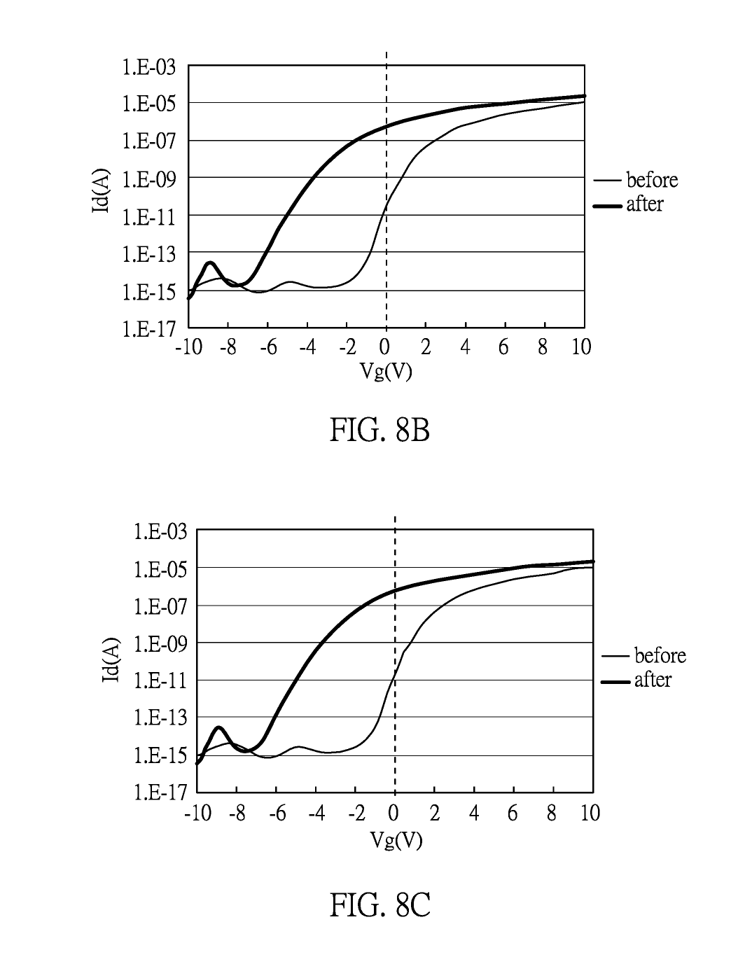

The results of the first thin film transistor unit 2 and the second thin film transistor unit 4 manufactured in Example 1 tested under current stress are shown in FIG. 7A and FIG. 8A, respectively. FIG. 7A shows that the Id-Vg curve of the first thin film transistor 2 is right-shifted as the test time increases. However, FIG. 8A shows that the shift of the Id-Vg curve of the second thin film transistor 4 is much smaller than the first thin film transistor 2 as the test time increases. Thus, if the second thin film transistor unit 4 is used as the thin film transistor unit for GOP circuit, high output current of the thin film transistor unit can be maintained. Therefore, the second thin film transistor unit 4, which comprises the second semiconductor layer 44 with a planar region, can serve as a better thin film transistor unit for GOP circuit, because it can maintain high output current compared to the first thin film transistor unit 2, which comprises the first semiconductor layer 24 with concave regions 241, 242. Note that the second thin film transistor unit 4 is not limited to the present example. In other examples, the second thin film transistor unit 4 with polycrystalline-silicon semiconductor is used as a GOP circuit.

The test conditions under negative gate stress are as follows: Vg=−30V, Vd=Vs=0 V, test temperature is 70° C., and test time is 3600 s. The test conditions under negative gate stress and back light stress are as follows: Vg=−30 V, Vd=Vs=0 V, test temperature is room temperature, test time is 3600 s, and under illumination of 8000˜10000 nits of backlight. The shift of TFT Vth was measured. The negative gate stress means that a negative voltage is applied to the gate electrode of a thin film transistor. The back light stress means that a light from the backlight is emitted to the thin film transistor.

The results of the first thin film transistor unit 2 and the second thin film transistor unit 4 manufactured in Example 1 tested under negative gate stress are shown in FIG. 7B and FIG. 8B, respectively. The results of the first thin film transistor unit 2 and the second thin film transistor unit 4 manufactured in Example 1 tested under negative gate stress and back light stress are shown in FIG. 7C and FIG. 8C, respectively. The back light was illuminated from the bottom 11a of the substrate 11 to the first source electrode 251 and the first drain electrode 252 (as shown in FIG. 2) or to the second source electrode 451 and the second drain electrode 452 (as shown in FIG. 4). The direction of the illumination is illustrated by arrowheads in FIG. 2 and FIG. 4.

As shown in FIG. 7B, the Id-Vg curve of the first thin film transistor unit 2 shows little change before and after applying negative gate stress under negative bias. In addition, as shown in FIG. 7C, there is only a small shift after applying negative gate stress and back light stress. However, as shown in FIG. 8B, the Id-Vg curve of the second thin film transistor unit 4 shifts to the left significantly after applying negative gate stress under negative bias. In addition, as shown in FIG. 8C, the Id-Vg curve shifts to the left significantly after applying negative gate stress and back light stress. These results indicate the leakage current of the first thin film transistor unit 2 does not increase significantly after applying negative gate stress or after applying negative gate stress and backlight stress at the same time. These results also indicate the first thin film transistor unit 2, which comprises the first semiconductor layer 24 with concave regions 241, 242, has excellent characteristics of a switch and is suitable to be used on the display region.

### Example 2

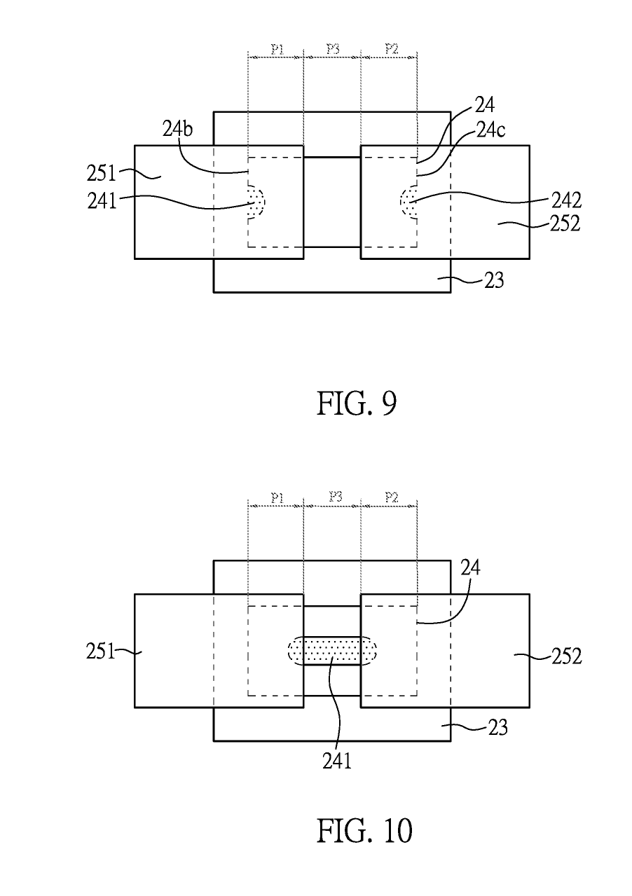

FIG. 9 is a top view of a first thin film transistor unit disposed on the display region of a display device of the present example. The structure of the first thin film transistor unit of the present example is similar to Example 1 except of the following. The shape of the concave regions 241, 242 is semicircle-like. The concave regions 241, 242 are located at edges 24b, 24c of the first semiconductor layer 24.

### Example 3

FIG. 10 is a top view of a first thin film transistor unit disposed on the display region of a display device of the present example. The structure of the first thin film transistor unit of the present example is similar to Example 1 except of the following. There is one concave region 241. The concave region 241 of the first semiconductor layer 24 of the present example is disposed at the first part P1 (under the first source electrode 251), the second part P2 (under the first drain electrode 252), and a third part P3 which is between the first part P1 and the second part P2. The shape of the concave region 241 of the present example is illustrated by an oval-like shape. However, in other examples of the present disclosure, the concave region 241 can adopt different shapes as long as the concave region 241 is disposed in the way as shown in FIG. 10.

### Example 4

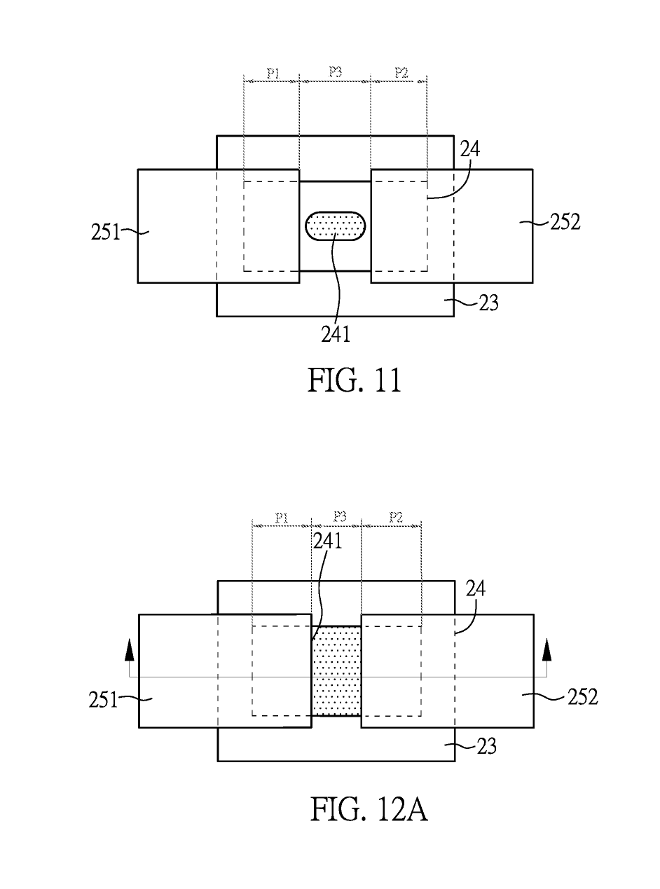

FIG. 11 is a top view of a first thin film transistor unit disposed on the display region of a display device of the present example. The structure of the first thin film transistor unit of the present example is similar to Example 3 except of the following. The concave region 241 of the first semiconductor layer 24 of the present example is disposed partially at the third part P3, which is between the first part P1 and the second part P2. The concave region 241 is not under the first source electrode 251 and the first drain electrode 252. Similarly, the shape of the concave region 241 of the present example is illustrated by an oval-like shape. However, in other examples of the present disclosure, the concave region 241 can adopt different shapes as long as the concave region 241 is disposed in the way as shown in FIG. 11.

### Example 5

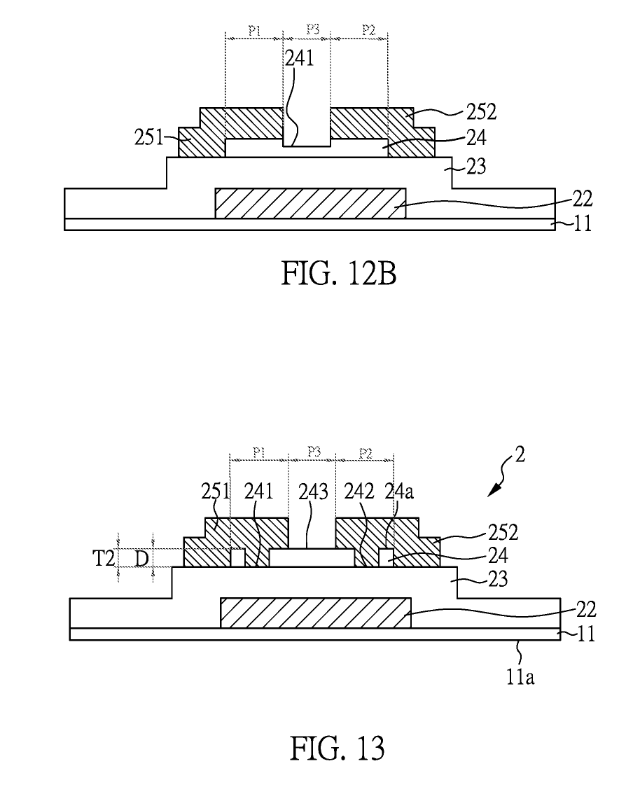

FIG. 12A and FIG. 12B are a top view and a cross-sectional view of a first thin film transistor unit disposed on the display region of a display device of the present example, respectively. The structure of the first thin film transistor unit of the present example is similar to Example 4 except of the following. The concave region 241 of the first semiconductor layer 24 of the present example is disposed entirely at the third part P3, which is between the first part P1 and the second part P2. The concave region 241 is not under the first source electrode 251 and the first drain electrode 252.

The manufacturing process of the concave regions 241 of the first semiconductor layers 24 in Example 4 and Example 5 can be the same as that in Example 1. After the formation of the first semiconductor layer 24, the concave region 241 was formed by an etch process. The formation of the first source electrode 251 and the first drain electrode 252 then followed. Alternatively, after the formation of the first semiconductor layer 24, the first source electrode 251 and the first drain electrode 252 were formed first. The concave region 241 was then formed by etching the first semiconductor layer 24 at a portion of the third part P3 as shown in FIG. 11 or at the entire third part P3 as shown in FIG. 12A and FIG. 12B.

### Example 6

FIG. 13 is a cross-sectional view of a first thin film transistor unit disposed on the display region of a display device of the present example. The structure of the first thin film transistor unit of the present example is similar to Example 1 except of the following. The concave regions 241, 242 of the first semiconductor layer 24 of the present example penetrate the first semiconductor layer 24. In other words, in the present example, the first thickness T1 in Example 1 is about 0 Å, which means the depth D of the concave regions 241, 242 of the first semiconductor layer 24 is about 100% of the third thickness T3 of the first semiconductor layer 24.

In the aforesaid examples 1˜6, bottom gate thin film transistor unit is used only for illustration. In the display panels of other examples of the present disclosure, the first thin film transistor unit disposed on the display region and the second thin film transistor unit disposed on the non-display region can also be top gate thin film transistor units.

In the present disclosure, the display panels made in the aforesaid examples 1˜6 can be used as liquid crystal display panels, organic light-emitting diode display panels, light-emitting diode display panels, or quantum dot display panels. In addition, the display panels made in the aforesaid examples can be used along with touch panels as touch display devices. At the same time, the display panels or the touch display devices made in the aforesaid examples can be used in any electronic devices displaying images, such as monitors, mobile phones, laptop computers, video cameras, cameras, music players, mobile navigation systems, and televisions.

Although the present disclosure has been explained in relation to its examples, it is to be understood that the features described in one example may apply to another example, or the features described in different examples can be combined o mixed without departing from the spirit and scope of the disclosure.

Although the present disclosure has been explained in relation to its examples, it is to be understood that many other possible modifications and variations can be made without departing from the spirit and scope of the disclosure as hereinafter claimed.

What is claimed is:

1. A display device, comprising:
a substrate having a display region; and
a first thin film transistor unit disposed on the display region, and comprising:
a first gate electrode disposed on the substrate;
a first insulating layer disposed on the first gate electrode;
a first semiconductor layer disposed on the first insulating layer, wherein the first semiconductor layer has a top surface which comprises a concave region and a non-concave region; and
a first source electrode and a first drain electrode disposed on the top surface of the first semiconductor layer;
wherein the first semiconductor layer has a first thickness corresponding to the concave region, and the first semiconductor layer has a second thickness corresponding to the non-concave region, wherein the second thickness is greater than the first thickness.

2. The display device as claimed in claim 1, wherein a difference between the first thickness and the second thickness is ranged from 50 Å to 500 Å.

3. The display device as claimed in claim 2, wherein the difference between the first thickness and the second thickness is ranged from 60 Å to 200 Å.

4. The display device as claimed in claim 1, wherein a difference between the first thickness and the second thickness is ranged from 10% of the second thickness to 100% of the second thickness.

5. The display device as claimed in claim 1, wherein a material of the first semiconductor layer comprises metal oxide.

6. The display device as claimed in claim 5, wherein the metal oxide comprises IGZO, AIZO, HIZO, ITZO, IGZTO, or IGTO.

7. The display device as claimed in claim 1, wherein the substrate has a non-display region located beside the display region, and the display device further comprising a second thin film transistor unit disposed on the non-display region, and the second thin film transistor unit comprises a polycrystalline-silicon semiconductor.

8. The display device as claimed in claim 1, wherein the substrate has a non-display region located beside the display region, and the display device further comprising:
a second thin film transistor unit disposed on the non-display region, comprising:
a second gate electrode disposed on the substrate;
a second insulating layer disposed on the second gate electrode;
a second semiconductor layer disposed on the second insulating layer; and
a second source electrode and a second drain electrode disposed on the second semiconductor layer,
wherein the second semiconductor layer has a third thickness, and the third thickness is greater than the first thickness.

9. The display device as claimed in claim 8, wherein a difference between the first thickness and the third thickness is ranged from 50 Å to 500 Å.

10. The display device as claimed in claim 9, wherein the difference between the first thickness and the third thickness is ranged from 60 Å to 200 Å.

11. The display device as claimed in claim 8, wherein a difference between the first thickness and the third thickness is ranged from 10% of the second thickness to 100% of the second thickness.

12. The display device as claimed in claim 8, wherein a material of the second semiconductor layer comprises metal oxide.

13. The display device as claimed in claim 12, wherein the metal oxide comprises IGZO, AIZO, HIZO, ITZO, IGZTO, or IGTO.

14. The display device as claimed in claim 1, wherein the first semiconductor layer comprises a first part and a second part which respectively corresponding to the first source electrode and the first drain electrode.

15. The display device as claimed in claim 14, wherein the concave region comprises two separated regions each disposed respectively at the first part and at the second part.

16. The display device as claimed in claim 14, wherein the concave region is disposed at the first part, the second part, and a third part between the first part and the second part.

17. The display device as claimed in claim 14, wherein the concave region is disposed partially at a third part between the first part and the second part.

18. The display device as claimed in claim 14, wherein the concave region is disposed entirely at a third part between the first part and the second part.
